(19) United States
(12) Patent Application Publication
(10) Pub. No.: US 2018/0074115 A1
(43) Pub. Date: Mar. 15, 2018

(54) RESIDUAL IONIC CLEANLINESS EVALUATION COMPONENT

(71) Applicant: GENERAL ELECTRIC COMPANY, Schenectady, NY (US)

(72) Inventor: Stephen Crynock, Milwaukee, WI (US)

(21) Appl. No.: 15/261,824

(22) Filed: Sep. 9, 2016

(51) Int. Cl. G01R 31/28; H05K 1/02; H05K 1/18; H05K 3/20; H05K 3/30

(52) U.S. Cl. CPC G01R 31/281; H05K 1/0268; H05K 1/181; H05K 2203/16; H05K 3/30; H05K 2201/10151; H05K 3/20

(57) ABSTRACT

Presented is a residual ionic contamination measurement device. The device comprises a component body defining at least one surface, and conductive traces along at least one surface of the component body defining at least one connection configured to connect the conductive traces by at least one of direct and indirect means to an electrical parameter measurement device, the conductive traces configured to remain in a passive state until connected to the electrical parameter measurement device, wherein when the conductive traces are connected to the electrical parameter measurement device, a signal is generated indicative of a level of residual ionic contamination.

### BACKGROUND

Ionic contamination of electronic assemblies may cause current leakage and short circuits. Dielectric materials that have been properly qualified for the production of printed circuit board (PCB) assemblies and other electrical assemblies have high surface and bulk resistivity. Low surface and/or bulk resistivity is almost always caused by either improper processing or by the presence of contaminants. Normally, the decrease in resistivity is the result of ionic conduction caused by non-reacted constituents or by ionic contaminants. Current leakage due to ionic conduction is often accompanied by the chemical reactions similar to those that occur during electroplating. However, instead of the plating of a metal film on the cathode the reactions form a plated tree-like structure called a dendrite.

Bridging of dendrites between conductors results in a short circuit; a failure mechanism commonly known as electrochemical migration (ECM). Factors affecting ECM can amongst others include: temperature, relative humidity, voltage bias, conductor material, conductor spacing, contamination type, and contamination amount. These factors can occur as greater or lesser effects alone or in combination with each other where the predominant factors, and synergistic combinations thereof, are often process specific. ECM can occur in three stages: path formation, initiation, and dendritic growth. Dendrites grow through the repeated migration and deposition of metal ions. Thus, ECM requires a path of electrolytic solution, and deposition of the metal at an oppositely biased conductor. Often, short-circuiting results in vaporization of a dendrite either in whole or in part, resulting in intermittent failures. It is more difficult to trace and locate these failures when they are formed underneath components where it is difficult to see them and where it is difficult to clean contaminants.

Under certain special cases, migration of metal ions and dendrite formation can occur along the interfaces of glass fiber and epoxy components within board laminates. Other board compositional elements can include: epoxies, polyimide laminates, resins, polymer resins, polymers, glasses, silicone, fiber based materials, textiles, and other materials suitable for electrical component assembly.

PCB production also includes many wet chemical treatments which all may leave residual contamination. Examples of wet chemical processes can include: desmearing of drilled holes, etching processes, plating of copper and surface finishes, and cleaning processes. One of the most contaminating processes used in PCB production is the application of solder. Solder can typically be applied using SMT reflow, wave, selective soldering process onto circuit board finishes consisting of Hot-Air Solder Leveling (HASL) or hot-oil fusing. Other circuit board finishes can include: electroless nickel immersion gold, immersion silver, immersion tin. Solder mask can also be applied over bare copper traces of a PCB. Various compositional elements of PCBs may also absorb flux ingredients to some extent, even at relatively low temperatures. Fluxes used for soldering of assemblies can also leave residues on the surface.

Surface contamination may take the form of halides such as bromides and chlorides including sub-species such as polyimide chlorides and bromides, ionically charged organic compounds, ionic inorganic compounds, LiCl.H₂O, KF, NaBr, CaCl₂.6H₂O, KBr, NaCl, KCl, KBr, KCl, NaF, and various other ionizable compounds. In specific, the terms “surface contamination” or “residual ionic contamination” or “contaminant” are used in typical fashion and generally refer to: any residue, intrinsic or extrinsic to the assembly process, capable of facilitating the migration of metal ions resulting in a breakdown of insulative resistance leading to the formation of an electrical fault. Contaminants may be susceptible to any of the factors affecting the ECM process as listed above in various combinations and strengths. Also, as used herein the term “electrical assembly,” although used in the context of PCB assembly and processes, also contemplates and includes other assembly configurations and materials where residual ionic contamination can potentially contribute to an electrical fault.

Developed in response to the need to measure levels of residual ionic contamination, and thus predict the robustness of electrical component assemblies, tests for residual ionic contamination can include: resistivity of solvent extract (ROSE), ion chromatography, Fourier transform infrared spectroscopy (FTIR), and surface insulation resistance (SIR).

More fully described and exemplified in protocols such as IPC-TM-650, MIL-P-28809, MIL-STD-2000, ECSS-Q-ST-70-08C, and their successors (all hereby incorporated herein by reference), the ROSE technique (sometimes called a Solvent Extract Conductivity test), and various spinoff sub-variants, is a common means of measuring residual ionic contamination. The premise of the technique is to generate an ion concentration measurement, calibrated to an equivalent known concentration of NaCl ions. The basic technique involves the application of a water-alcohol solution to a batch-representative electrical assembly by means of spraying or soaking with or without agitation. Practitioners next measure the electrical resisitivity of the solution and then calculate a value for the level of contamination. The contamination level is usually calculated by correlating the resistivity measurement to a calibrated concentration of NaCl. Typical calculated contamination units returned are μg cm⁻² where the mass is the equivalent amount of NaCl and the area is a unit value of the surface area of the electrical assembly. The protocol is often time consuming, requiring immersion times ranging from 1 min to several hours with often only one assembly serving as representative for an entire batch. It is difficult to rapidly track changes in bulk production and track sources of contamination.

The various ROSE sub-protocols and processes vary in terms of duration; solution composition; if the solution is sprayed, oscillated, or dipped into; solution volumes; ratios of solution components; alcohols used; static or dynamic regeneration of solution; standoff of the electrical components; deadband (inability to register if solvent reaches a resistivty above the measuring capability of the probe); carbon dioxide absorption into the solution; etc. Even automated instrumentation can return widely variable measurements for the same process. In all instruments, the solvent will also absorb heat due to pumps moving the solvent and friction in the plumbing.

In addition to variances induced by equipment and procedural variables, ROSE testing does not accelerate an underlying failure mechanism. Thus, there is no direct correlation between obtained values and actual time to equipment failure. Instead, acceptable cleanliness values used are derived post hoc from field experience. Additional a priori models for time to failure based on electrochemical principles have been developed and proposed; these models include: Arrhenius, Eyring, Barton and Bockris, DiGiacomo, Peck, Howard, and CALCE, amongst others. These models, and other adaptations, do not currently all account for residual contamination measurements or for all the variables currently known to affect ECM.

On its own the ROSE protocol cannot distinguish between the types of ions present in the extracted solution. This makes it difficult to track and eliminate sources of contamination. ROSE, or ROSE-like protocols are thus often subsequently paired with ion chromatography techniques. Ion chromatography, used alone or in combination with ROSE, is often used to track anions dissolved in solution such as: fluoride, chloride, bromide, nitrate, phosphate, and sulfate. Other process-specific techniques are also possible. However, like ROSE, this technique generates a measured value over the whole area of the electrical assembly, and there is no clear correlation between measured value and reliability. There is no ability to locally test a specific sub-section of an assembly. This technique also takes 15 minutes or more per sample and requires separately trained and dedicated personnel to conduct the test and interpret results.

An additional technique to identify unknown contaminants utilizes Fourier transform infrared spectroscopy (FTIR). FTIR spectroscopy utilizes infrared energy to excite fundamental vibrational and associated rotational-vibrational modes of molecules in the mid-infrared frequency range. The vibrational modes correspond to relevant molecular structures. Attenuated total reflectance (ATR) allows for direct analysis of liquid and solid samples. Typical practice takes the form of analyzing unknown residues gathered by rinsing an electrical assembly in a ROSE-like process. Like the ROSE and ion chromatography techniques described above, sample times greater than 15 minutes are common. It is also common to test either batch-representative assemblies or to utilize process-specific testing modules. FTIR also requires skilled operators to run the equipment and conduct the test, and, like the ion chromatography technique, sample analysis is often conducted off-site.

Defined more fully in IPC-9201 and its successors, hereby incorporated by reference, Surface Insulation Resistance testing (SIR) testing applies an electrical bias to an inter-digitated test pattern placed either in a test square of material or a test area of a PCB assembly. The test is capable of determining the effects of both ionic & non-ionic contaminants. Since it is etched into a printed circuit board, or a process-representative test assembly (sometimes known as a “test square”), it is able to demonstrate the electrochemical compatibility between all process materials. SIR is quantitative, not qualitative. Thus, SIR can be used to monitor material and process trends. Since SIR accelerates a failure mechanism, it is thought capable to predict reliability of the end process product. In general, a high SIR value indicates that electrochemical migration is unlikely and a low SIR value indicates an increased risk for dendrite formation even though there is no clear correlation between SIR and a tendency for dendrite formation. The SIR test typically takes not less than 72 hours to carry out, requires skilled operators, and although it can possibly determine if the end product will be reliable, it cannot determine what material or part of the process is causing or contributing to the failure. Over the lengthy measurement times required for the test, it is also possible for SIR values obtained for a contaminated board to approach those of a clean board, rendering the test valueless.

Time domain reflectometry (TDR) analysis starts with the propagation of an energy pulse into a system and the subsequent observation of the energy reflected by the system. In the telecommunications industry TDR is often used to identify locations of discontinuities in cables. In the agricultural field, TDR probes are used to measure porous media water content and electrical conductivity. In particular, water content is inferred from the dielectric permittivity of the medium, whereas electrical conductivity is inferred from TDR signal attenuation. It is also possible to use TDR to measure salinity and ionic solutes of bulk soils and other materials based on the attenuation of the applied signal voltage as it traverses the medium of interest.

Radio frequency identification devices (RFID) also can employ TDR techniques, sometimes coupled with frequency signature techniques to encode information. RFID and TDR allow for the usage of passive antenna-type structures to convey information. Further, additional techniques make use of passive magnetic structures incorporated into the RFID and TDR elements to provide additional layers of information and measurement capabilities. These techniques either singly or in combination can be used to measure the dielectric properties of a material.

Thus there is need for a rapid test, indicative of assembly quality, conducted by non-skilled operators, performed on-site, responsive to multiple assembly points, and run on every assembly in a lot rather than a representative.

### BRIEF DESCRIPTION

The exemplary non-limiting embodiments described herein relate to apparatuses and methods for determining residual ionic contamination in electrical assemblies. In a more specific sense, there is described a generally applicable apparatus and method of measuring residual ionic contamination in the context of a printed circuit board assembly. Those skilled in the art will recognize that the embodiments are not limited to solely this structure and that other forms and assemblies are equally possible and valid.

One exemplary non-limiting embodiment of a residual ionic contamination measurement device is demonstrated by a component body defining a surface. Conductive traces formed along the surface of the component body define at least one connection configured to connect the conductive traces by at least one of direct and indirect means to an electrical parameter measurement device. The conductive traces are configured to remain in a passive state until connected to the electrical parameter measurement device. When the conductive traces are connected to the electrical parameter measurement device, a signal is generated indicative of a level of residual ionic contamination. The electrical parameter measurement device can measure at least one of: voltage, amperage, inductance, magnetic flux, capacitance, radio frequency resonance, and time domain reflectance.

For the embodiment described above, in at least one instance, the surface of the component body may be placed in contact with a material containing residual ionic contamination. It is also possible that the conductive traces are formed to contain at least some resistive, capacitive, resonant, or inductive properties. The traces may also be configured to resonate to at least one of: a radio frequency, a magnetic pulse, and a time domain reflectivity pulse. The conductive traces may also be created using multiple materials. The traces could also be patterned in at least one of parallel, grid, arcuate, circular, and cross-hatched patterns. Finally, the traces could also be placed at the edge of a surface, in the middle of a surface, or at an intermediate position between the edge and the middle.

In another exemplary non-limiting embodiment, the component body may contain at least a second surface which contains a signal processing unit configured to connect to the conductive traces and process a signal from the conductive traces when connected to the electrical parameter measuring device. The second surface (or another alternate surface) may also contain the electrical parameter measuring device. The second surface (or another alternate surface) may contain other electrical elements as part of an electrical assembly.

Another exemplary non-limiting embodiment of a residual ionic contamination measurement device is demonstrated via an electrical component. The body of the component defines a surface. Conductive traces are along the surface of the component body and define at least one connection configured to connect the conductive traces directly or indirectly to an electrical parameter measurement device. The conductive traces are configured to remain in a passive state until connected to the electrical parameter measurement device. There is also a circuit board comprising a component placement area. The electrical component is attached to the printed circuit board at the defined component placement area. When the conductive traces are connected to the electrical parameter measurement device, a signal is generated indicative of a level of residual ionic contamination.

For the embodiment described above, it possible that multiple component bodies may be placed in a plurality of placement areas. It is also possible that that the placement areas may be at the edge, middle, or an intermediate area between the edge and the middle of the printed circuit board.

For the above embodiment, the conductive traces may be configured to contain at least one of resistive, capacitive, resonant, and inductive properties. The traces may also be configured in at least one of parallel, grid, arcuate, circular, and cross-hatched patterns.

For the above embodiment, the component placement area may contain additional conductive traces. These conductive traces may be configured to interface with the conductive traces on the component body. The conductive traces may contain any appropriate electrical elements as described throughout and may also be patterned in any configuration.

Another embodiment of a residual ionic contamination measurement device is illustrated by way of a measurement method for residual ion contamination comprising: Placing conductive traces configured to measure residual ionic contamination alongside a surface of an electrical component body. Defining a means to connect an electrical parameter measurement device to the conductive traces. Placing the etched component onto a predefined area of a printed circuit board. Finally, connecting an electrical parameter measurement device to the conductive traces, generating a measurement representative of residual ionic contamination.

For the method described above, it is conceived that the measurements generated by the electrical parameter measurement device are combinable with one or more mathematical models to generate a measurement representative of residual ionic contamination. Exemplary, non-limiting mathematical models may include one or more of the Arrhenius, Eyring, Barton and Bockris, DiGiacomo, Peck, Howard, and CALCE models, or combinations thereof. Said method, in at least one embodiment, leading to enhanced time to failure predictions.

It is also possible to configure the conductive traces in order to induce ECM failure when connected to an electrical parameter measurement device.

In some embodiments the electrical parameter measuring device may be integrated as part of the generic component. The electrical parameter measuring device may be directly connected to the conductive traces through the component body, or it may be configured to indirectly connect to the conductive traces through the component body. The component body may permanently house the electrical parameter measuring device, or it may be configured to allow placement and subsequent removal of the electrical parameter measuring device. The component body may contain other electrical elements as part of an electrical assembly or it may solely contain the electrical parameter measuring device. It may also contain an element that pre-processes or otherwise configures information from the traces and presents it into a format readable by an electrical parameter measuring device.

### BRIEF DESCRIPTION OF THE DRAWINGS

Other objects, advantages and novel features of the invention will become apparent from the following detailed description of the invention when considered in conjunction with the accompanying drawings, in which like characters represent like parts throughout the drawings, wherein:

FIG. 1 is a component bottom side with multiple conductive trace patterns.

FIGS. 2A and 2B are examples of conductive trace patterns and placements.

FIGS. 3A and 3B are examples of conductive trace patterns and placements.

FIG. 4 is an example of component placement in an electrical assembly.

FIG. 5 is a side-view cutaway of an electrical component with traces and an integrated electrical parameter measurement device.

FIG. 6 is a top/side perspective view of a conductive trace along a surface of a component body.

### DETAILED DESCRIPTION

Embodiments of the invention relate to systems and methods of generally measuring the residual ionic contamination of electrical systems. Some of the non-limiting embodiments are described herein with respect to the residual ionic contamination of printed circuit boards with pick-and-place components. Practitioners skilled in the art, however, will readily recognize the applicability and scope of the invention to cover other areas where measurement of residual ionic contamination on a surface is necessary. Further, different combinations of elements from the various non-limiting example embodiments may be practiced singly, together, or interchangeably between embodiments.

Practitioners skilled in the art may also appreciate some of the numerous advantages associated with the described embodiments. By way of non-limiting examples, including: decreased sample time, the ability to test multiple areas of an assembly, the ability to test more than a representative sample from a batch, the ability to generate process-specific components and test patterns, a reduction in personnel to perform a test, a reduction in the skill level of the personnel to perform testing, the elimination of solvents, the ability to test at each stage of a process, etc.

As used herein, the term “component” refers to a generic element of an electrical assembly. Non-limiting example components can include: chips, inductors, capacitors, resistors, transistors, diodes, etc. The term can also refer to a generic part designed for testing portions of the electrical assembly or process steps. A component may be permanently affixed to the electrical assembly, or it may be removable to allow substitution of another component or later reattachment.

These components, and the various means of connecting them may also be referred to as “electrical elements” that would form an “electrical assembly.” The term appendages “elements” and “assembly” are indicative of scale arrangements. Electrical “elements” may be pieced together into “assemblies” that, in turn, may form elements of larger assemblies.

The term “component body” refers to the physical structure of a component; in the context of a “surface” on a component body, it is understood that a surface may be an integral, intrinsic part of the body, or it may take the form of an additional layer or layers attached to the main, integrated, body of the component.

Also, as used herein, the term “electrical parameter measurement device” refers to a device, instrument, or apparatus used to measure an unknown variable. Examples of measured variables can include: resistance, inductance, capacitance, resonance, magnetic strength or flux, voltage, time domain reflectance and other similar variables. The “electrical parameter measurement device” may also induce changes in the measured system through the application of energy either directly, such as through a connection point, or indirectly, such as by transmitting a radio signal.

Also, as used herein, the term “passive” refers to a non-activated state in terms of information reporting or signal generation. It may also encompass an energetic component (i.e., a state of energy flowing through the component), but this is not necessary. Usage in one sense does not preclude usage in the other sense.

Also, as used herein, the term “connect” is broadly generic and may refer to: direct, physical connections, between objects as well as indirect means of conveying information between objects, or that one object acts upon or affects another. Finally, as used herein, the term “signal” refers to the transfer of information, regardless of format. A “signal” may consist of a combination of several physical phenomena read together, singly, or in various combinations thereof. A “signal” may also contain information regarding multiple variables or multiple component values used in the calculation of a measurement.

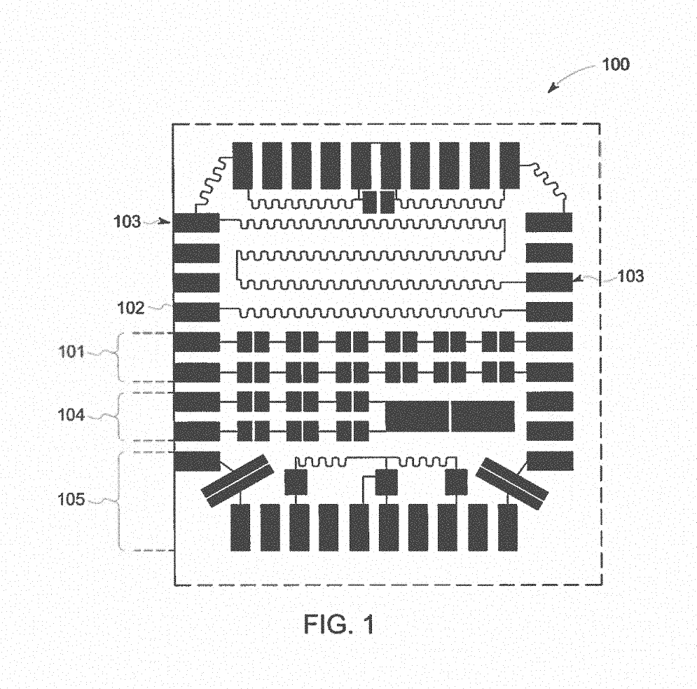

Also, as used herein, the term “conductive trace,” in at least one exemplary non-limiting embodiment, generally refers to an electrically conductive element, collection of electrically conductive elements and/or electrically conductive pathways(s) arranged to form a functional pattern along a surface of a component. Example embodiments of which are demonstrated in FIGS. 1-3. A “conductive trace” pattern may be composed of one or more materials forming one or more individual elements of the overall pattern. The term “conductive trace” may encompass both the singular and the plural wherein individual electrically conductive elements, or “traces” may make up a larger trace pattern. For example, a single “conductive trace” may be joined to another “conductive trace” to form a larger, “conductive trace” pattern, and the new larger/extended pattern can have supplemental properties beyond either individual trace alone. Further, one conductive trace pattern may be wholly independent from another conductive trace pattern, and information gathered from each may be combined to generate one or more measurements indicative of different aspects of possible residual ionic contamination. Finally, not all elements of a “conductive trace” are required to be electrically conductive; some materials used in forming the conductive trace may be resistive, insulative, capacitive, inductive, magnetic, and/or resonant, and the like.

Examples included in the above definitions are provided as non-limiting, non-exclusive, demonstrations of generally accepted characteristics of the defined terms. Those skilled in the art can recognize variant interpretations or definitions specific to a particular need or state that can affect the scope and applicability of an example or definition.

FIG. 1 presents an example surface of a component body 100. Various conductive trace patterns are present as example configurations of: a series capacitor network 101, a resistor 102, resistance loop 103, capacitance and inductive combination 104, and a resistor, inductor, and capacitor network 105. These elements can appear singly or in combinations. Elements may be combined to tailor the output of the traces to a particular electrical parameter measuring device. For example, one set of traces may contain physical contact points for contact with a voltmeter while simultaneously containing resonance elements for non-contact electrical parameter measurement devices such as an RFID reader. These traces may be combined and various elements substituted between each other.

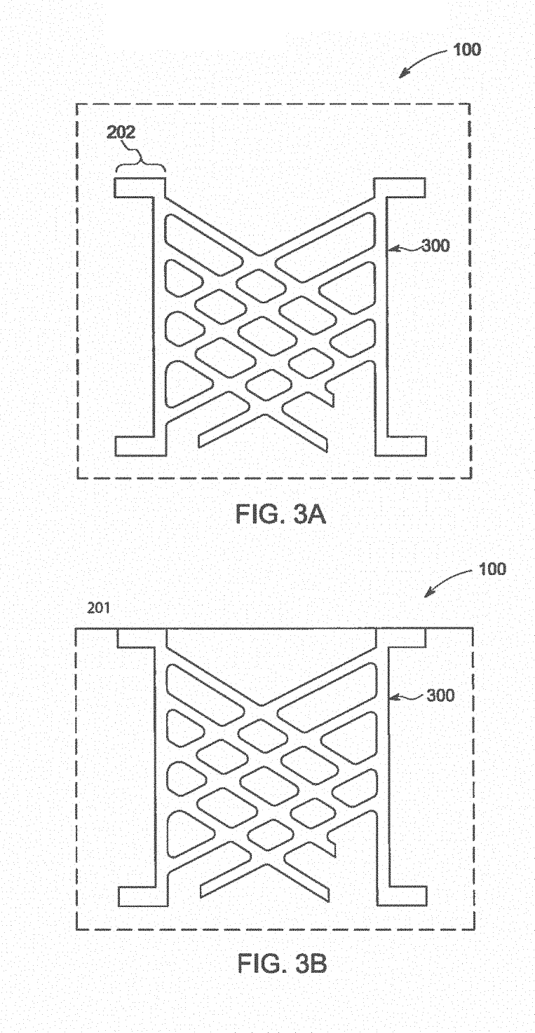

As another example, different element groups like those illustrated in FIG. 1, may be split between the component body surface and an additional surface, such as the predefined area 402 of FIG. 4. The traces may be wholly distinct, independent traces such as elements 101-105 shown in FIG. 1, or they may link together to form a larger assembly with different capabilities. Those skilled in the art will recognize that traces may be placed alongside the component body through any mechanical, chemical, or energetic, active, or passive means. Traces may be integrated as part of the component body, or form an additional surface layer separate from a component body surface. The traces may be exposed, or might be covered with a protective layer. The protective layer may be configured to regulate ion migration to the conductive traces.

Different trace groupings such as those illustrated in FIG. 1, may be made of similar or a multiplicity of materials. Thus, one trace network could be made of multiple materials either within the same trace or different from another trace. These materials may be preselected based upon target ion species, process elements that are desired for testing, or component material compatibility. Material composition of the traces may differ from element to element, i.e., capacitive elements may contain materials different from resistive elements, both of which differ from an interconnecting element.

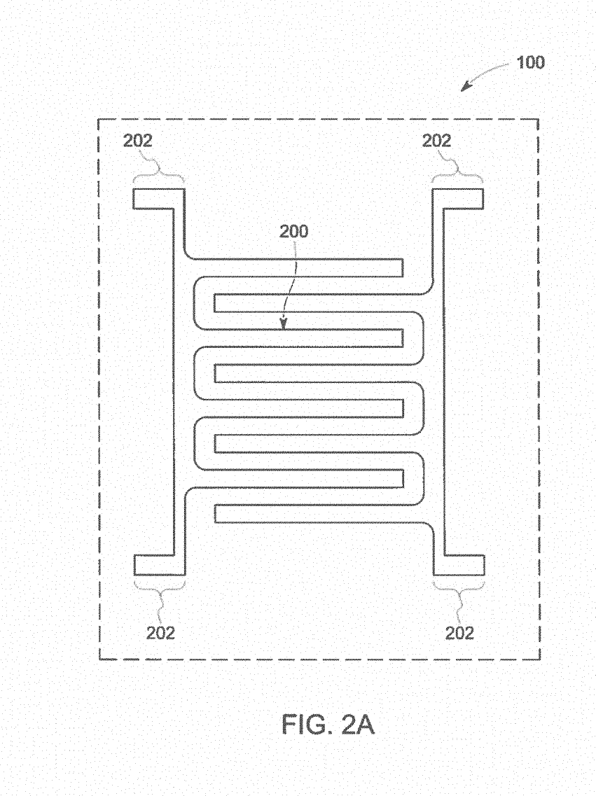

FIG. 2 presents an example surface of a component body 100. The conductive traces 200 are shown as a set of interlacing combs placed anywhere on the surface of the component (FIG. 2A) or adjacent to the edge of the component body 201 (FIG. 2B) with electrical connection points 202.

Each comb may be of similar materials or dissimilar material; each protrusion of the comb may follow in a similar vein of material composition. Similarly, the gaps between the comb and comb protrusions may be composed of a variety of different materials in order to configure the structure for a specific ion species, process variable, or testing function. The halves of the comb may be split with one half placed on the component body and the other placed in the predefined area 402 (FIG. 4). A coating may be applied over the combs to control ion migration and to select target species or to facilitate a failure mechanism.

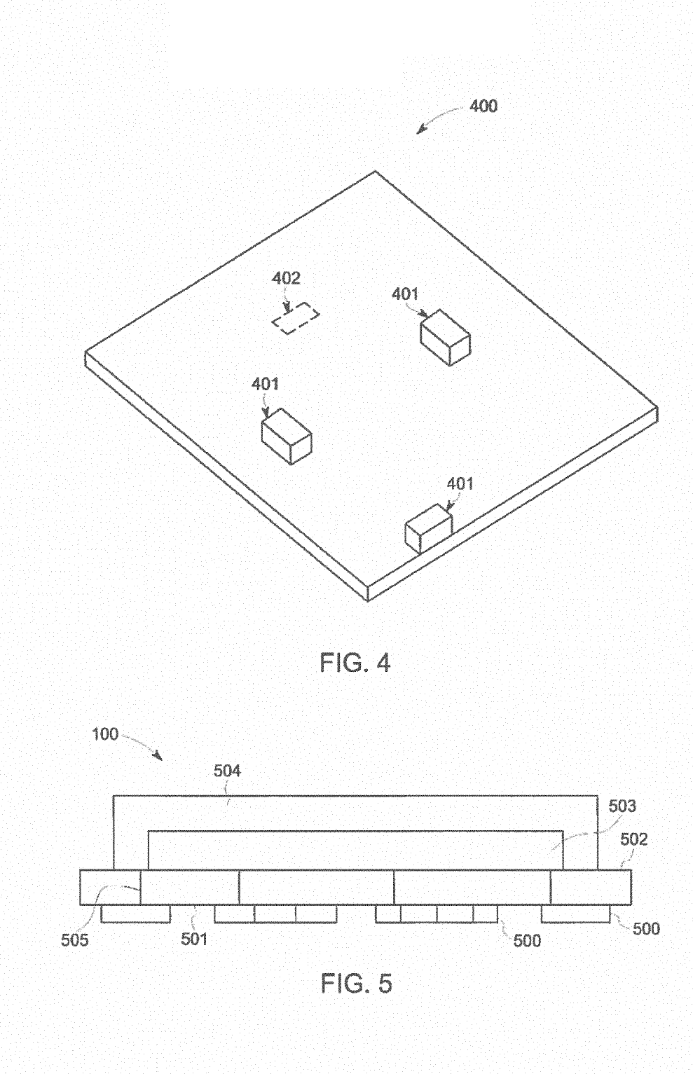

Electrical connection points 202 may differ in shape and composition depending upon location of the pattern and desired form of connection to the electrical parameter measuring device. Electrical connection points 202 may also allow connection through a hole (such as via 505 in FIG. 5) leading to the electrical connection point. Spacing of the comb may vary from one end of the pattern to the next such that gaps at one end are narrower than those at another; or, alternatively, gaps in the middle are different from those at the ends. The spacing between gaps and the material composition of the combs, protrusions, or gaps, may be altered in both size and composition such that the comb is configured to induce ECM failure when an energetic source is applied, such as through an electromagnetic parameter measuring device.

The component body 100 may contain a multiplicity of surfaces with differing patterns and electrical elements. The component body 100 may also form an element of a larger electrical assembly. The component body 100 may further be configured to be removable from the electrical assembly. This would allow access to the comb structure for further examination of an underlying fault post-testing. The component body 100 could then be reattached to the electrical assembly or it could be discarded or reused without affecting the final operation of the electrical assembly.

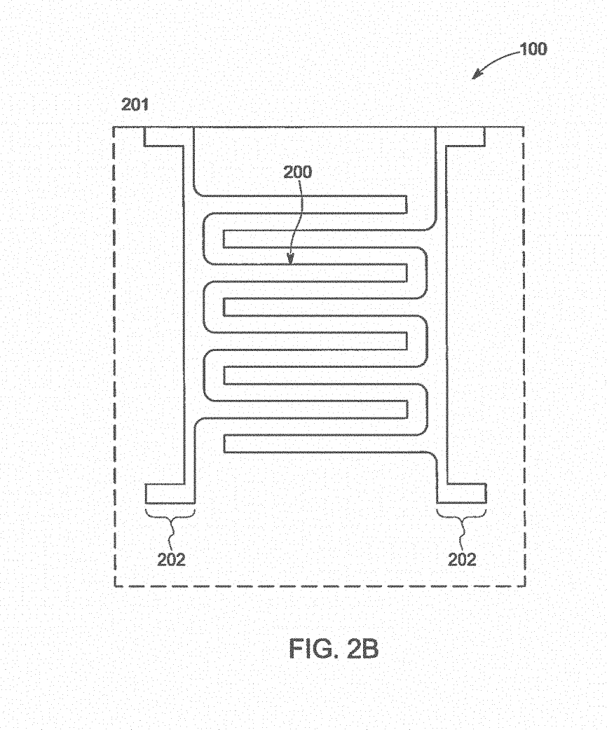

FIG. 3 presents an example surface of a component body 100. The conductive traces 300 are shown in an interlacing hatched formation placed anywhere on the surface of the component (FIG. 3A) or adjacent to the edge of the component body 201 (FIG. 3B). As illustrated, the gaps between the hatched formation may be irregular in shape and size, they may also be of uniform spacing and shape. The hatched formation may contain any or all of the properties as described above for the comb pattern either singly, or in multiple combinations.

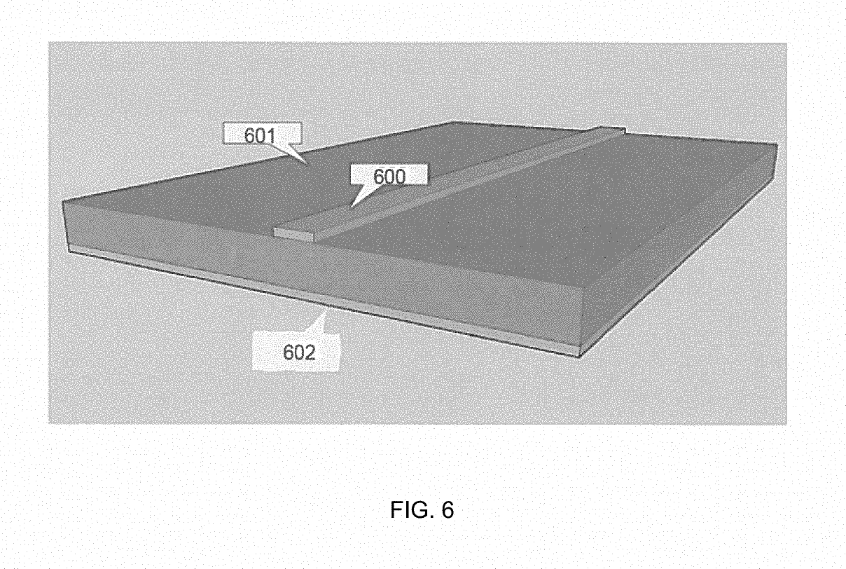

In at least one of the embodiments described above, the conductive traces having been deposited or otherwise added to the component body are raised relative to a surface of the component body, such as, for example, a raised conductive trace on a microchip or printed circuit board (PCB) (see e.g. conductive trace 600 on surface 601 of component body 602, as illustrated in FIG. 6). It should be noted, however, that the conductive traces could be etched into, injected into, printed onto, painted onto, or otherwise added to the component body by known manufacturing and/or advanced/additive manufacturing methods; hence the method or methods used in adding or placing the conductive traces on the component body should not be interpreted in a limiting sense, and the traces could be raised, depressed and/or coplanar with the a body surface.

FIG. 4 presents an example of an electrical assembly 400 with a plurality of components 401 placed at a predefined area 402 configured for the purpose of measuring residual ionic contamination. The predefined area 402 may simply be an empty space, or one or more surface preparation techniques may be applied. The predefined area may be configured with materials used as part of a process for creating an electrical assembly. The predefined area may also require removal of a surface layer so that a component 401 may be partially embedded, or able to access a different layer. The predefined area may also include connection points for either the component, an electrical parameter measurement device, or the conductive traces.

Components 401 may potentially be placed anywhere on the board and be either stand-alone or as part of an electrical assembly. Components placed on a printed circuit board or other integrated circuit system may be elevated to a pre-determined stand-off height from the board, they may be flush with the board surface, or layers of the board may be removed in order to facilitate embedding the component into the board. Components assembled with a stand-off height may have the gap between the component and the board left open or filled with a substrate bridging a surface of the component with the predefined area 402.

In another embodiment, the predefined area 402 may contain conductive traces that may be configured to complement, supplement or extend the capabilities of the conductive traces on the component 401 or component body 100. In some embodiments, conductive traces on component 401 or component body 100 may directly or indirectly interact with conductive traces placed in the predefined area 402. In some instances, the conductive traces from each surface may form a unified pattern configured to generate a signal. In other embodiments, the conductive traces on each surface may not directly interact with each other.

In some embodiments, such as a component with a stand-off height, a third material may bridge the two sets of conductive traces, allowing the generation of a signal when connected to an electrical parameter measuring device. In other instances, the electrical connection points that are part of one set of electrically conductive traces may convey a signal from the other set of traces. In another embodiment the traces may be constructed such that a signal from one or both is modified through the presence of the other trace or via the connection between them.

FIG. 5 presents an example side view cutaway of an example component body 100, with exaggerated conductive traces 500 analogous to any of the trace patterns as shown in previous figures and discussed above, a bulk material separating the surface where the conductive traces are located 501 from an opposite surface 502, containing an electrical parameter measuring device 503, contained in a housing 504, and connected to the conductive traces by way of vias 505. In another embodiment, opposite surface 502 may instead be a surface adjacent to or semi-contiguous with the surface where the conductive traces are located 501.

Although the electrical parameter measurement device 503 is shown directly connected to the conductive traces 500 by way of vias 505, it is also possible that the electrical parameter measuring device may be indirectly connected to the conductive traces and may, thus, receive a signal from the conductive traces via an indirect connection. In another embodiment the electrical parameter measuring device may be configured to connect using both direct and indirect connections by accessing different conductive trace groupings or sub-sections of a conductive trace. In another alternative embodiment, electrical parameter measuring device 503 may be a signal pre-processor or other component designed to refine signal from the traces and present it in a format usable by an electrical parameter measuring device.

In a final embodiment, the housing 504, or any of the surfaces 501, 502 may also contain additional electrical elements (not shown) such that the component body 100 may be integrated as a functional part of an electrical assembly not configured to measure residual ionic contamination. Alternatively, the housing 504 may be removable and electrical parameter measuring device 503 may be replaced with other electrical elements configured to enable the space taken by the component body 100 to be used as part of an electrical assembly.

The written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims. Additionally, when an element is preceded by the article “a” or “the” the article should be interpreted as meaning one, or more than one, of that element. The use of the singular can also contemplate the use of the plural. Elements may also be interchangeably used within and across differing embodiments. Embodiments may use some or all of the elements and still fall within the scope of the invention. Finally, elements may nest in that smaller elements may compose larger elements while still retaining an individual or differentiated identity while part of a larger unit.

What is claimed is:

1. A residual ionic contamination measurement device comprising:
a component body; and
at least one conductive trace along a surface of the component body, the at least one conductive trace defining a connection configured to connect, directly and/or indirectly, the at least one conductive trace to an electrical parameter measurement device, the at least one conductive trace configured to remain in a passive state until connected to the electrical parameter measurement device,
wherein when the at least one conductive trace is connected to the electrical parameter measurement device, a signal is generated indicative of a level of residual ionic contamination.

2. The device of claim 1 wherein the electrical parameter measurement device measures at least one of: voltage, amperage, inductance, magnetic flux, capacitance, radio frequency resonance, and time domain reflectance.

3. The device of claim 1 wherein the surface of the component body comprising the at least one conductive trace is at least one of: over, under, proximate, and in contact with a material containing an unknown amount residual ionic contamination.

4. The device of claim 1 wherein the at least one conductive trace is: connected to an edge of the surface of the component body, placed in the middle of the surface of the component body, and/or placed intermediate to the middle and edge of the surface of the component body.

5. The device of claim 1 wherein the component body further comprises at least a second surface comprising a signal processing unit configured to connect to the at least one conductive trace and process a signal from the at least one conductive trace when connected to the electrical parameter measuring device.

6. The device of claim 1 wherein the second surface of the component body further comprises the electrical parameter measuring device.

7. The device of claim 1 wherein the second surface of the component body contains additional electrical elements as part of an electrical assembly.

8. The device of claim 1 further comprising:
a circuit board comprising at least component placement area,
wherein the component body is attached to the printed circuit board at the at least one component placement area; and, when the at least one conductive trace is connected to the electrical parameter measurement device, a signal is generated indicative of a level of residual ionic contamination.

9. The device of claim 8 wherein a plurality of component bodies are placed in a plurality of component placement areas.

10. The device of claim 9 wherein the plurality of placement areas comprises an edge, middle, and/or intermediate area of the printed circuit board.

11. The device of claim 8 wherein a secondary conductive trace is positioned in the at least one component placement area.

12. The device of claim 11 wherein the secondary conductive trace is configured to interface with the conductive trace on the component body.

13. The device of claim 1 wherein the conductive trace is composed of at least two materials.

14. A measurement method for residual ion contamination comprising:
placing a conductive trace configured to measure residual ionic contamination alongside a surface of a component body;
defining a connection point for an electrical parameter measurement device in the conductive trace;
placing the component body onto a predefined area of a printed circuit board; and,
connecting an electrical parameter measurement device to the conductive traces, generating a measurement representative of residual ionic contamination.

15. The method of claim 14 wherein the electrical parameter measurement device is configured to measure at least one of: voltage, amperage, inductance, magnetic flux, capacitance, radio frequency resonance, and time domain reflectance.

16. The method of claim 14 wherein the values measured by the electrical parameter measurement device are combined with a mathematical model to generate a measurement representative of residual ionic contamination.

17. The method of claim 14 further comprising placing the predefined area of a printed circuit board in at least one of: along an edge, in the middle of, and in an intermediate area between the edge and the middle of the electrical assembly.

18. The method of claim 14 further comprising configuring the conductive trace to induce ECM failure when connected to an electrical parameter measurement device.

19. The method of claim 14 further comprising defining at least a second surface of the component body, providing a signal processing unit attached to the at least a second surface configured to connect to the conductive trace and process a signal from the conductive trace when connected to the electrical parameter measuring device.

20. The method of claim 14 further comprising integrating the electrical parameter measuring device with at least a second surface of the component body.

21. The method of claim 14 further comprising placing additional electrical elements configured for use in an electrical assembly on at least a second surface of the component body.

22. The method of claim 14 further comprising creating the conductive trace using multiple materials.
